(19) United States
(12) Patent Application Publication
(10) Pub. No.: US 2008/0041441 A1
(43) Pub. Date: Feb. 21, 2008

(54) SOLAR CONCENTRATOR DEVICE FOR PHOTOVOLTAIC ENERGY GENERATION

(76) Inventor: Zalman Schwartzman, Rehovot (IL)

Correspondence Address: David Klein;DEKEL PATENT LTD., Beit HaRof' im, 18 Menuha VeNahala Street, Room 27, REHOVOT, omitted

(21) Appl. No.: 11/759,254

(22) Filed: Jun. 7, 2007

(30) Foreign Application Priority Data
Jun. 29, 2006 (IL) 176618

(51) Int. Cl. H01L 31/052

(52) U.S. Cl. 136/246

(57) ABSTRACT

A solar energy concentrator lens is formed by a prism array. Each prism is designed to deflect the incident solar rays and fully illuminate a rectangular photovoltaic cell with uniform intensity. The combination of multiple prisms uniformly illuminating a common target area yields concentrated uniform illumination across the target area.

### FIELD OF THE INVENTION

This invention relates to a new optical concentrator, designed for concentrated photovoltaic solar energy generation.

### BACKGROUND OF THE INVENTION

Solar energy conversion modules that convert sunlight to electrical power typically employ photovoltaic cells that directly convert sunlight to electrical energy.

Concentrating methods for increasing the light intensity on the cell are usually employed. Such methods include using concentrator lenses and/or reflectors to focus the sun on the cell. See, e.g., U.S. Pat. No. 6,020,554 which utilizes a Fresnel lens in combination with rectangular reflectors closely mounted to the photovoltaic cell.

Two axis sun tracking servomechanism have been developed to keep the lens axis directed to the sun at all times during the day (e.g., U.S. Pat. Nos. 4,628,142 and 4,498,456).

The photovoltaic cell is considered to be the most expensive component in a solar energy converter, therefore increasing the solar illumination intensity by concentrators is considered a very promising cost reduction design approach if low cost concentrators are utilized. It is common to design multi module arrays on two axis tracking panels, each module is usually designed with a rectangular lens that allow maximum panel area utilization for collecting the solar energy. See, e.g., U.S. Pat. No. 5,125,983.

The amount of electrical energy generated by the photovoltaic cell is related to the intensity of solar illumination the cell absorbs. Several research groups showed that when concentrated solar illumination is implemented with specially designed photovoltaic cells, the conversion efficiency can increase above what is achievable with non concentrated designs, reaching levels of 30% and higher.

Photovoltaic cells for concentrated solar energy conversion are relatively small, thin, rectangular or square semiconductor dies that is cut from a large semiconductor wafer after appropriate processing.

See, e.g. Spectrolab Inc. (a Boeing company) publication “photovoltaic products”, describing “Triple Junction Concentrator Solar Cells”. These cells are designed for concentration ratio of X200-X400 suns with efficiency greater than 30%. Their active area is square and they are available in dimensions of 1×1 or 0.5×0.5 centimeters.

Photovoltaic cells that are designed for concentrated solar generators require uniform illumination for best efficiency and reliability. It is common in concentrated photovoltaic solar energy generation to use a standard circular Fresnel lens designed for point focus and to place the photovoltaic cell at a distance shorter than the focal length to obtain the desired concentration ratio.

Since optical imaging is not required for solar concentrators, it is common to slightly modify the circular Fresnel groove facet design to improve uniformity of the target illumination. See, e.g., U.S. Pat. Nos. 4,799,778 and 6,399,874.

There are several problems with this approach. First, when a rectangular lens is cut from circular grooved Fresnel lens in an attempt to match the target, the intensity of the sun projected on the target area is non uniform, leading to loss of conversion efficiency. The reason is that loses of Fresnel lens are more significant as the distance from center is larger. These loses will be even more significant at the corners of the rectangular target.

The second problem is that the sharpness of the boundaries is usually poor; a significant area out of the cell is illuminated leading to further loss of efficiency.

It is a common practice to use a secondary concentrator/homogenizer in form of a rectangular reflector or a light guide mounted near the cell, this solution is far from being ideal in terms of illumination uniformity, adds extra part count and cost.

Molded sphere profiled lenses have similar problems if cut in rectangular shape to match a rectangular target, also leading to non uniform illumination and loss of efficiency.

### SUMMARY OF THE INVENTION

It is an object of the present invention is to provide an optical concentrator for photovoltaic solar energy generation, that more accurately and uniformly concentrate the solar illumination on a rectangular photovoltaic cell.

It is a related object to provide a solar energy generator module that utilizes such an optical device that concentrates solar energy with sufficient accuracy, on a rectangular photovoltaic cell, so that no secondary optical concentrator or homogenizer is required.

These objects, as well as others, that will become apparent upon reference to the following detailed description and accompanying drawings, are accomplished by a new solar energy concentrating device, which is specially designed for high intensity uniform illumination of a rectangular photovoltaic cell. The device is comprised of a multiple solar radiation deflecting elements each deflecting element fully illuminating a common target area that contains a photovoltaic cell. A multitude of such solar radiation deflecting elements, illuminating a common target area yields high intensity uniform illumination of the cell.

A solar energy concentrator lens is formed by a prism array. Each prism is designed to deflect the incident solar rays and fully illuminate a rectangular photovoltaic cell with uniform intensity. The combination of multiple prisms uniformly illuminating a common target area yields concentrated uniform illumination across the target area.

The photovoltaic cell that is mounted on a heat sink, convert the uniform concentrated solar illumination to electrical energy.

In a preferred embodiment of the invention, a multitude of rectangular Fresnel prisms are arrayed to form a flat, thin, low cost solar concentrating lens. Each Fresnel prism is designed with a multitude of straight, parallel Fresnel grooves, profiled and oriented to deflect the sun's rays to fully illuminate a rectangular photovoltaic cell, resulting concentrated uniform solar radiation on the cell.

The lens and the photovoltaic cell are mounted in a housing being installed on a two axis sun-tracking structural grid forming a solar energy generating panel.

The concentrating device can be in form of a concentrating lens mounted in a housing that supports at least one photovoltaic cell therein. A heat sink is thermally connected to the photovoltaic cell to dissipate excessive heat and a transparent cover optionally protects the surface of the lens and the cell from the environment. Positive and negative contacts are connected to the cell to transfer the electrical energy to the load.

The housing in which the lens is mounted is part of a multi module solar generator panel. A two axis sun tracking servomechanism is designed to move the panel and keep the lens optical axis directed to the sun during the day. A concentrating lens according to the present invention can be formed from a multitude of prisms, each prism is designed to deflect the incident sun's rays and fully illuminate a rectangular photovoltaic cell at a pre determined focal distance with well defined uniform illumination.

The uniform intensity of the incident sun's rays is maintained by each prism all the way through to the target because the light is refracted by planar surfaces only and therefore the rays are kept parallel and with uniform intensity.

In one embodiment of the present invention, a multitude of prisms are combined together, to form one solid lens with the side facing the sun having a multi facet shape and the side facing the target area being planar. Close match between adjacent facets of the lens can be achieved by appropriate design of each prism height. Each facet on the multi facet side of the lens is designed to fully illuminate the target area with uniform intensity.

The combination of many planar facets deflecting solar rays to a common target area enhances the light intensity without sacrificing the uniform nature of the sun illumination. The amount of concentration will depend on the number of facets projecting light on the target area and generally, for a given cell, will be a function of the lens area. The lens can be designed with rectangular, triangular or hexagonal shape so that an assembly of multiple lenses can be formed, to fully utilize the illuminated area.

In another embodiment, the lens has a multi facet side facing the sun and a staggered concave side facing the target, thus saving weight and cost. Furthermore, the concave side of the lens can also be designed with multi facet shape, each facet designed for refracting light to fully illuminate the rectangular photovoltaic cell.

In a preferred embodiment of the invention, a multitude of rectangular Fresnel prisms are arrayed to form a flat, thin, low cost concentrating lens. Each rectangular Fresnel prism is designed to deflect the sun's rays and project a well defined uniform illumination spot fully illuminating a rectangular photovoltaic cell.

Each of the said rectangular Fresnel prisms is designed with a multitude of straight parallel Fresnel grooves, with orientation and facet angle designed to deflect solar rays to a rectangular target while keeping the rays parallel and therefore fully and uniformly illuminating the target.

It is a common knowledge from Fresnel lens theory that the losses created within a specific segment of the lens, increase when the distance of this segment from the center of the lens increase. The reason is that the groove facet angel have to increase at the outer area of the lens to achieve more deflection, therefore groove density has to increase as well to keep groove depth under a predetermined limit, leading to more refraction, diffraction and other types of optical loses.

It is also clear to anyone familiar with Fresnel lens theory that rectangular Fresnel prisms that are located at the edges of the lens will have sharp groove facet angle leading to higher losses but the illumination uniformity across the target area will be preserved.

In the Fresnel lens according to the present invention, the design of any arbitrary Fresnel prism for the lens has straight parallel grooves and has common facet angles across the rectangular Fresnel prism area, hence the illumination contributed by each groove is a uniform intensity stripe and all stripes combine to a well defined uniformly illuminated rectangular light spot.

The combination of many rectangular Fresnel prisms deflecting the sun's rays to a common rectangular target yield a well defined, enhanced intensity illumination spot on the rectangular photovoltaic cell, while preserving the uniform nature of the solar illumination.

In another embodiment, a concave multi facet concentrating reflector can be formed by a multitude of planar mirrors, each mirror designed to reflect the solar rays and fully illuminate a rectangular photovoltaic cell with uniform intensity.

The uniform intensity of the incident sun's rays is maintained by each planar mirror all the way through to the target because light is reflected by planar surfaces only and therefore the rays are kept parallel and with uniform intensity.

The combination of multiple mirrors reflecting solar rays to illuminate a common target area, enhance the light intensity without sacrificing the uniform nature of the sun illumination.

There are many advantages in using reflectors compared to lenses for solar energy concentration e.g. no absorption losses, less diffraction loss and no color dispersion, resulting better concentration of wide solar spectrum. Close match and smooth transition can be achieved between adjacent mirrors of the concave reflector hence a thin walled concave reflector can be manufactured by methods that are commonly used for manufacturing headlight reflectors in the car industry. The amount of concentration, depend on the number of facets projecting light on the target area and generally, for a given photovoltaic cell, will be a function of the reflector area. The reflector can be designed with rectangular, triangular or hexagonal shape so that an array of reflectors can be formed to optimally utilize the panel area.

In another embodiment of the present invention, a Fresnel mirror can be created, having straight parallel grooves in the surface of a flat material, all groove facet angles in a Fresnel mirror are constant and the surface of the grooved side is coated with highly reflective layer.

A Fresnel mirror and a Fresnel prism are similar devices in terms that they both deflect parallel uniform light to a target area while preserving the uniform intensity. A flat Fresnel reflector having multitude of rectangular Fresnel mirrors arrayed together can be designed, having the advantage of saving space and cost while preserving other advantages of a reflector compared to a lens when used for solar energy concentration. The combination of multiple Fresnel mirrors reflecting solar rays to a common target area enhances the light intensity while preserving the uniform nature of the sun illumination.

The amount of concentration, depend on the number of Fresnel mirrors projecting light on the target area and generally and for a given photovoltaic cell, will be a function of the reflector area. The Fresnel reflector can be designed with rectangular, triangular or hexagonal shape so that an array of lenses can be formed to create a multi reflector solar generator panel fully utilizing the panel area.

### BRIEF DESCRIPTION OF THE DRAWINGS

FIG. 1 is perspective view showing a solar energy module with a solid lens according to the present invention with 25 planar facets on the top side facing the sun and a planar surface on the bottom side facing the photovoltaic cell.

FIG. 2 is a top view and side view of the solid lens of FIG. 2 FIG. 3 is cross sectional view of the lens of FIG. 2 and shows the sun's rays refracted to illuminate the target area.

FIG. 4 is perspective view of a solar energy generator module with four lenses similar to that of FIG. 2 combined together into one lens assembly.

FIG. 5 is a perspective view of a solid molded lens according to the present invention, with 25 planar facets on the top side and staggered concave profile on the bottom side.

FIG. 6 is cross sectional view of the lens of FIG. 6 and shows the sun's rays refracted to illuminate the target area.

FIG. 7 is a cross sectional view of some possible molded lenses designed according to the present inventions.

FIG. 8 shows a cross sectional view of a prism and a Fresnel prism deflecting solar radiation to illuminate a rectangular target area.

FIG. 9 is a top view and cross sectional view of 25 square Fresnel prisms, arrayed to form a lens according to the present invention.

FIG. 10 is cross sectional view of the Fresnel lens of FIG. 9 and shows the sun's rays refracted to illuminate the target area.

FIG. 11 is perspective view showing a solar energy generating module with the Fresnel prism array lens of FIG. 9.

FIG. 12 is perspective view of a solar energy generator module with four Fresnel prism array lenses combined together to form a lens assembly.

FIG. 13 shows two possible Fresnel groove profiles that can be used for a rectangular Fresnel prism in the array of FIG. 9

FIG. 14 shows the orientation angle of an arbitrary Fresnel groove in an arbitrary Fresnel prism in the array of FIG. 9

FIG. 15 is an enlarged view of the target area illuminated by the lens of FIG. 9

FIG. 16 is a cross sectional view of a concentrating reflector, photovoltaic cell, heat sink and protective cover according to the present inventions.

FIG. 17 is a cross sectional view of a concentrating Fresnel reflector, photovoltaic cell and heat sink plate according to the present inventions.

FIG. 18 shows a die for pressing a single Fresnel prism or a Fresnel mirror.

### DETAILED DESCRIPTION OF THE PREFERRED EMBODIMENTS

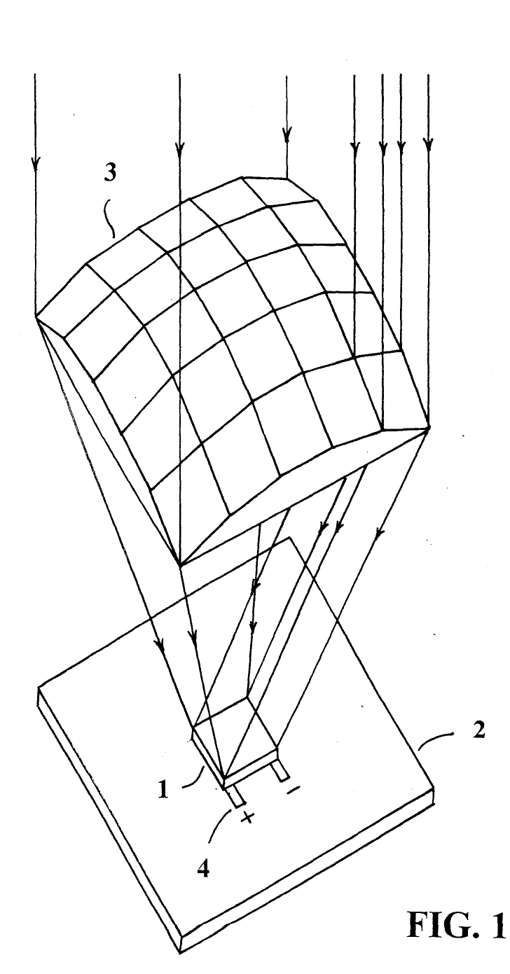

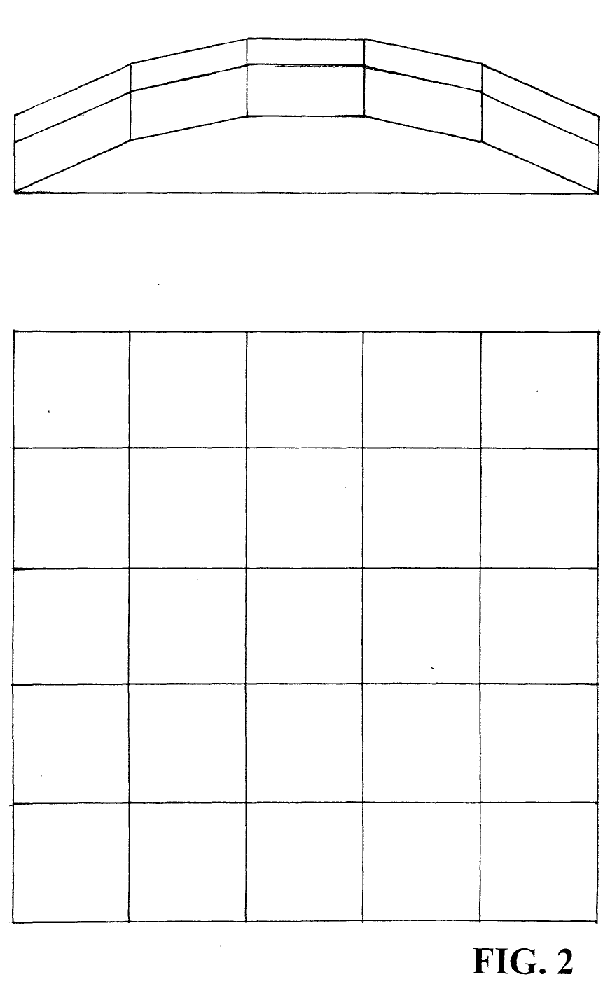

As illustrated in FIG. 1, a square photovoltaic cell 1 is mounted on a heat sink plate 2. A 25 facet concentrating lens 3 in accordance with the present invention is located above the photovoltaic cell; the cell is within a concentrated illumination target area of the lens, converting the solar energy to electrical energy being transferred to the load through terminals 4.

25 facets were chosen for convenience of drawing. However, all the descriptions apply to any number of facets and shapes, as required for a specific concentration ratio and specific photovoltaic cell, by appropriately modifying the lens design.

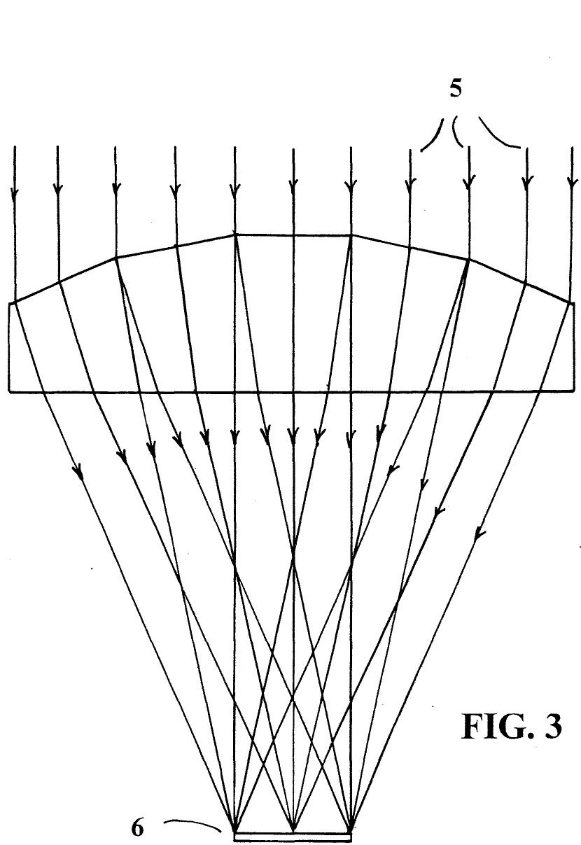

FIG. 2 is a top view and side view of the lens of FIG. 1 showing each facet as a square when viewed from the top.

FIG. 3 is a cross section view of the lens of FIG. 2, showing the solar rays 5 refracted by each planar facet of the lens, fully illuminating the rectangular target 6 with well defined uniform light intensity.

The basic aspect of the invention is to map the solar light from each of the planar facets of the lens to fully illuminate the rectangular photovoltaic cell while keeping refracted rays parallel.

The illumination from multiple of planar facets combine together on the common target area to yield concentrated light that fully and uniformly illuminates a photovoltaic cell that is located within the target area of the lens, converting the concentrated solar energy to electrical energy.

Some pre determined margin can be designed into the lens, so that the illuminated target area is somewhat larger than the photovoltaic cell, accounting for possible structural misalignment and sun tracking errors.

The solar energy generator module described in FIG. 1 can be packaged into an integrated module with at least one lens, one heat sink and one photovoltaic cell, mounted in a housing with or without a transparent protection cover. A multitude of such modules can be mounted on a sun tracking constructional grid to form a solar energy generator panel.

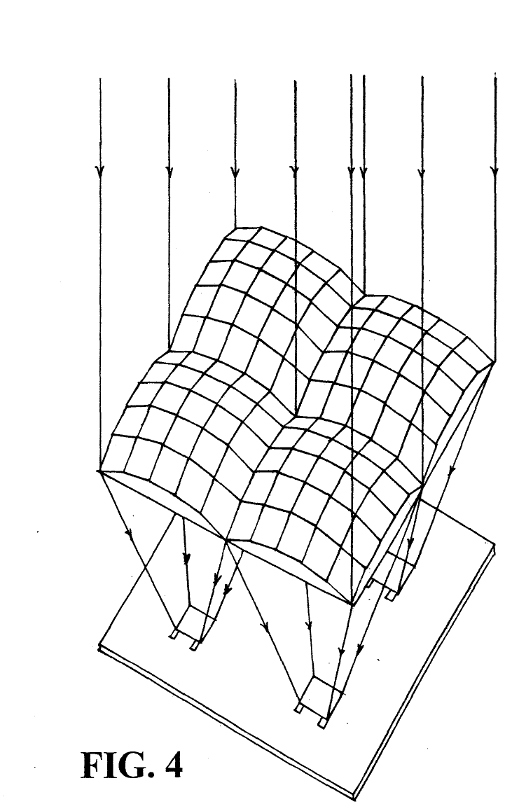

FIG. 4 illustrate a design with four lenses and four cells combined together to form a multi cell power generating module sharing common housing for hardware cost saving. Any number of lenses and photovoltaic cells can be combined together in a similar way to optimize a specific module design.

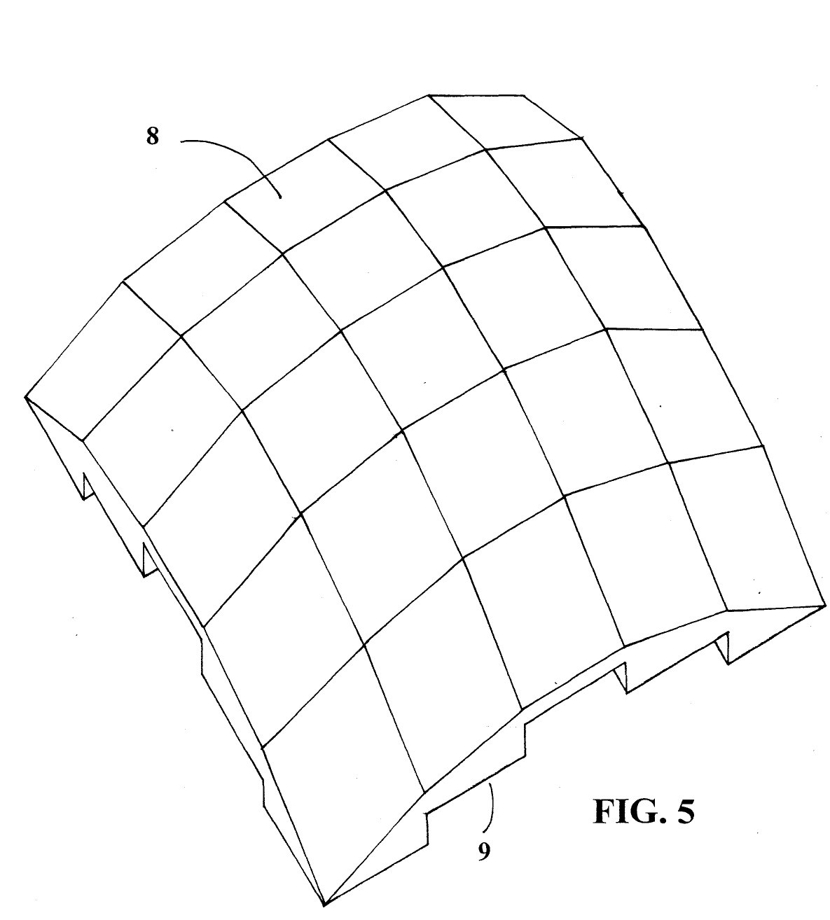

Another embodiment of the lens of the present invention is illustrated in FIG. 5. The lens surface 8 facing the sun is similar to the lens of FIG. 1 and the surface 9 facing the target is staggered, saving lens weight and cost. The penalty of this design is some extra refraction loses.

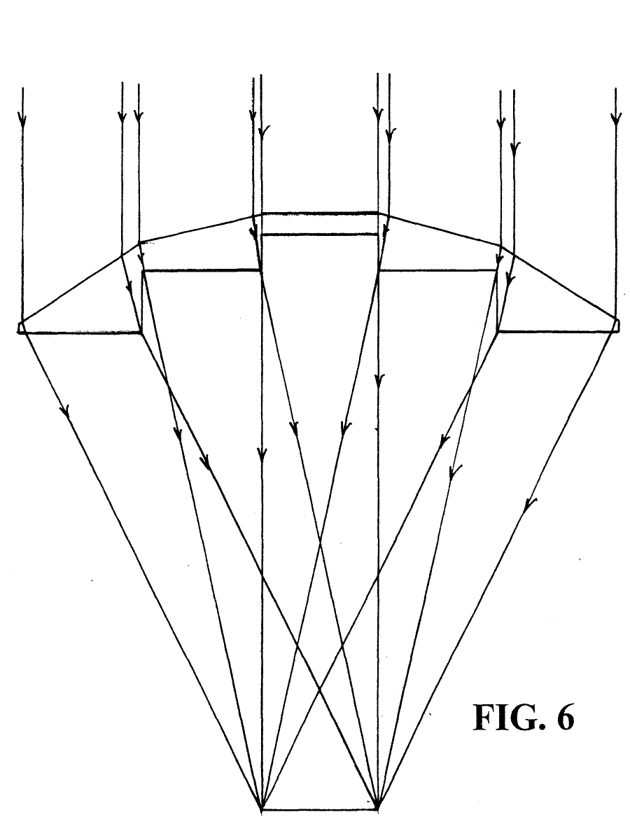

A cross sectional view of this lens is shown in FIG. 6, illustrating solar rays refracted by each planar facet illuminating the target, it can be seen that rays in the boundary area between adjacent facets are hitting vertical walls of the staggered side of the lens and lost.

The side of the lens facing the target can also be designed with concave multi facet shape according to the present invention with each facet designed to fully illuminate the photovoltaic cell.

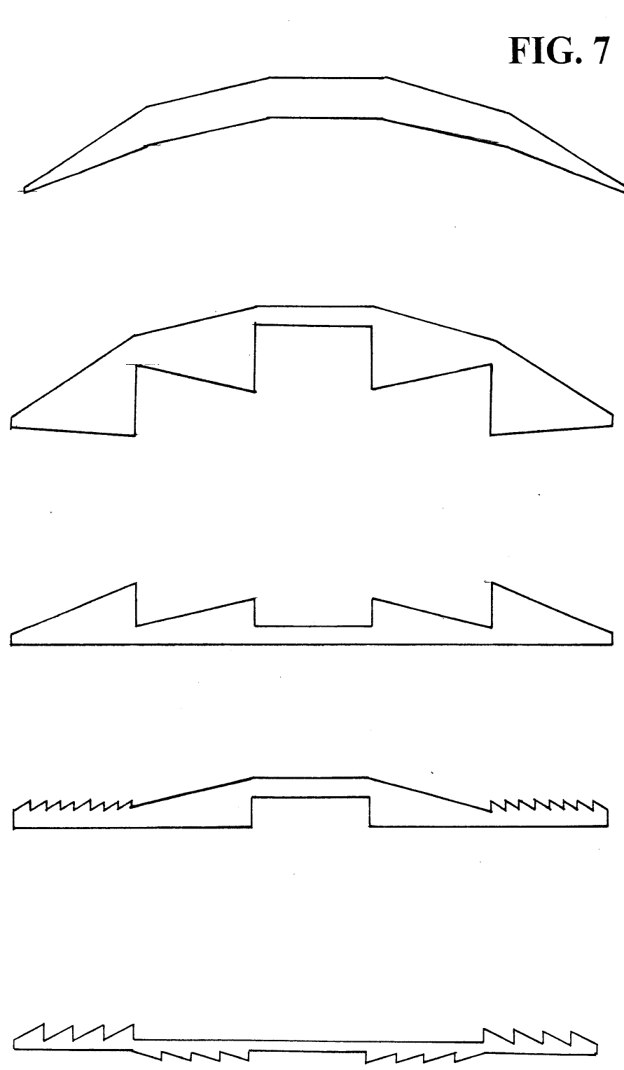

Some other possible lens profiles are depicted in FIG. 7; however there is no intent to limit the present invention to these profiles and many other lenses can be designed according to the basic aspects of the present invention.

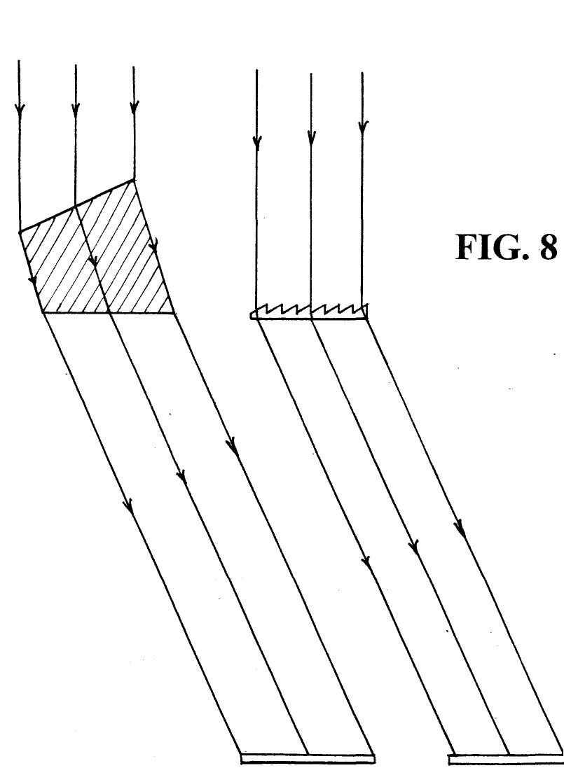

FIG. 8 shows a solid prism and a Fresnel prism, both similarly deflecting solar radiation and illuminating a rectangular photovoltaic cell.

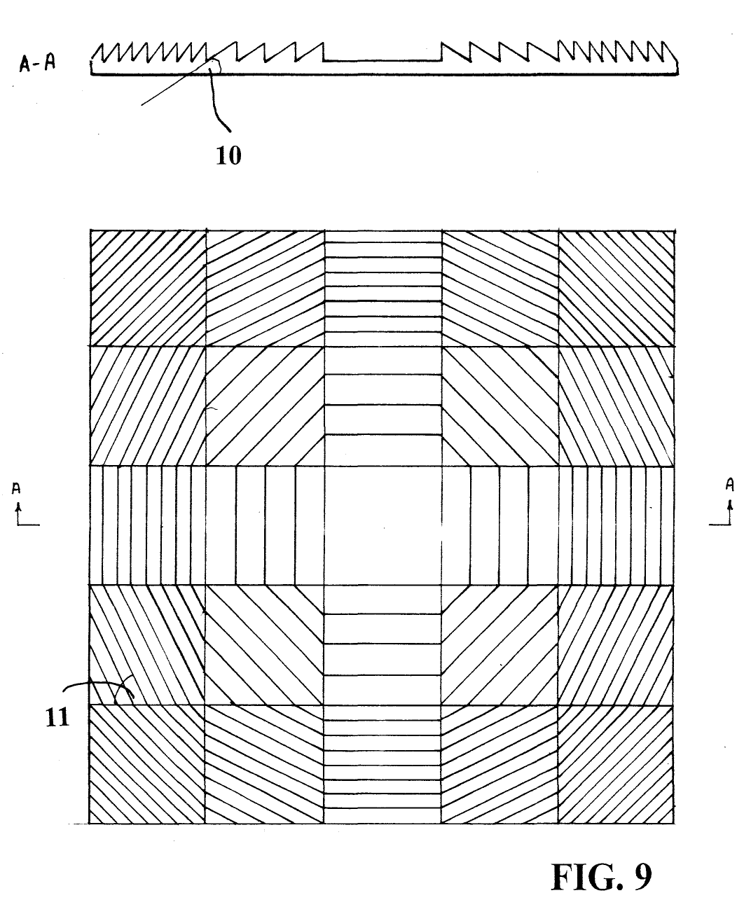

FIG. 9 illustrate a preferred embodiment of the invention, showing the top view and a cross sectional view of 25 square Fresnel prisms, arrayed to form a flat, thin low cost concentrating lens.

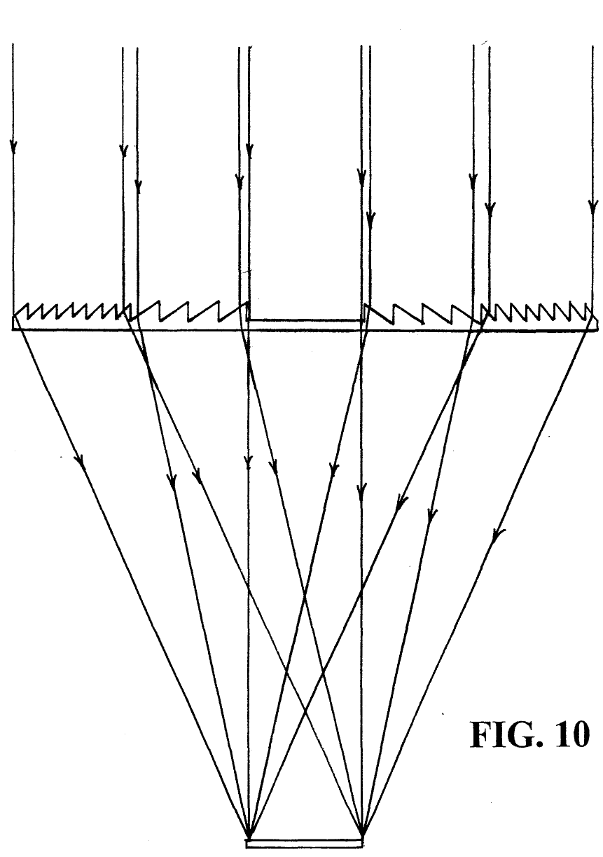

FIG. 10 shows a cross sectional view of the Fresnel lens of FIG. 9, showing each rectangular Fresnel prism deflecting the sun's rays to project uniform intensity light fully illuminating a rectangular photovoltaic cell located within the target area.

The dimension of each square Fresnel prism is equal to or larger than the photovoltaic cell designed to be illuminated by the lens, to account for possible structural misalignment and tracking errors.

As can be seen in FIG. 9 each square Fresnel prism is designed with a multitude of straight, parallel Fresnel grooves, with facet angle 10 and orientation angle 11 being designed to project a well defined, uniformly illuminated, square light spot on a rectangular photovoltaic cell.

Furthermore, it has been found that the straight parallel grooves of each rectangular Fresnel prism, in the lens according to this preferred embodiment, can be designed with grooves that closely match with grooves in adjacent rectangular prisms as can be seen in FIG. 9, thus allowing for smooth groove transition between adjacent prisms, forming closed polygonal contours, minimizing diffraction and refraction loses and allowing easier production.

The illumination from multiple of Fresnel prisms combine together on the common target area to yield concentrated light that fully and uniformly illuminate a square photovoltaic cell that is located within the target area.

Although a 25 square Fresnel prism array lens is illustrated in FIG. 9, there is no intent to limit the invention and the design can be easily modified to any number, shape and size of prisms as required for a specific photovoltaic cell and sun concentration goal.

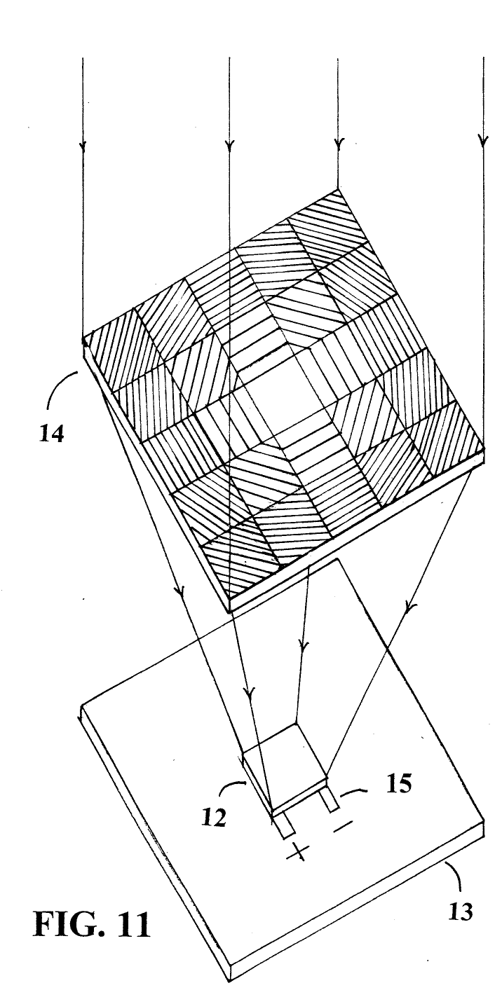

FIG. 11 shows a square photovoltaic cell 12 mounted on a heat sink plate 13. A 25 Fresnel prism array concentrating lens 14 in accordance with the present invention is located above the photovoltaic cell, the cell is within a concentrated illumination area of the lens, converting the solar energy to electrical energy being transferred to the load.

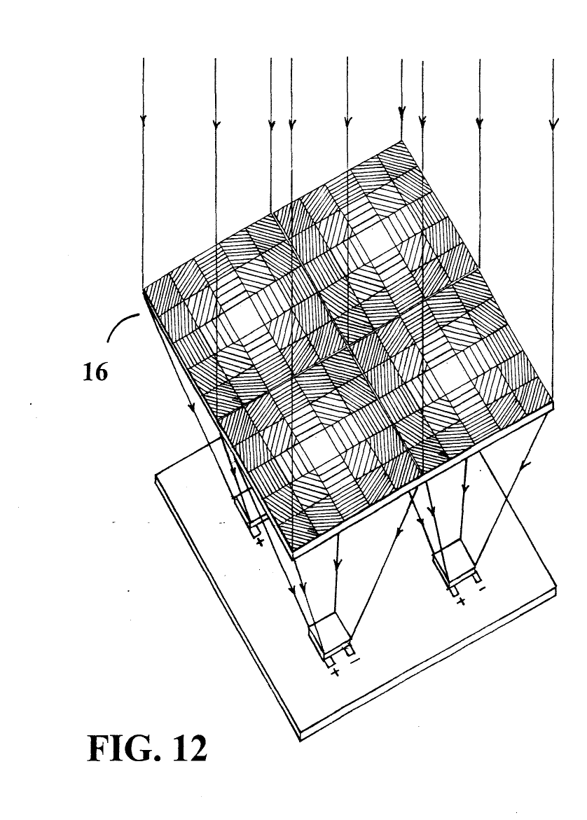

In FIG. 12, four Fresnel prism array lenses are combined to form a multi lens assembly 15, illuminating four photovoltaic cells.

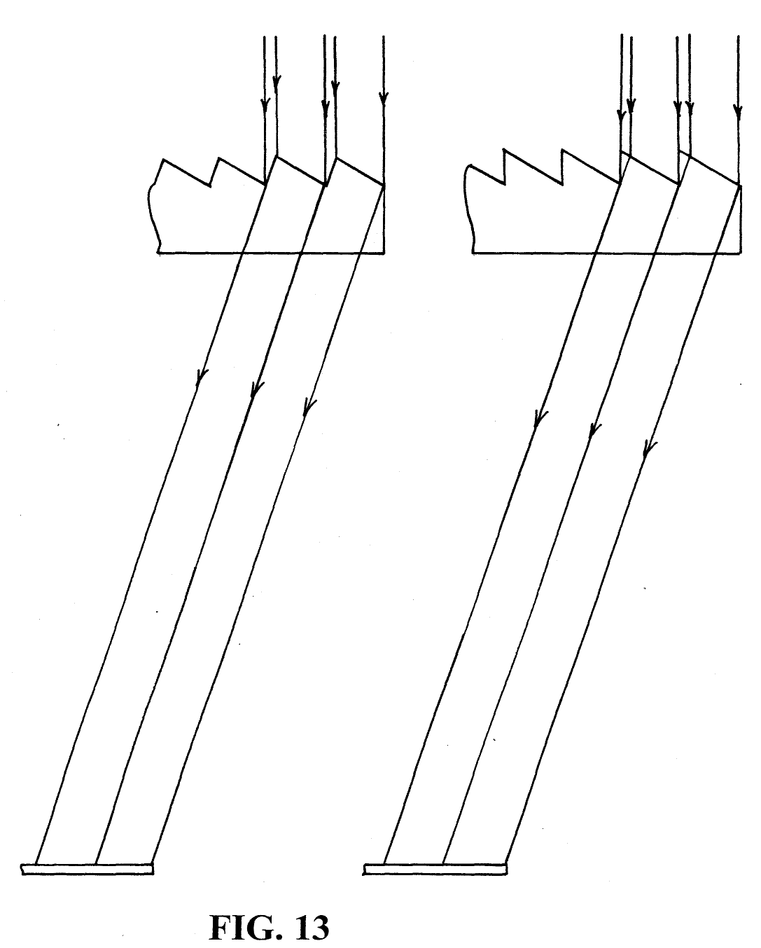

FIG. 13 shows two possible Fresnel groove profiles within a Fresnel prism and the optical refraction geometry of solar rays refracted by them. It can be seen from the optical geometry that as the groove facet angel increase, refraction losses will increase respectively. These loses as well as absorption and diffraction loses are unavoidable with Fresnel grooves design. From the drawings in FIG. 13 it is clear that in both groove profiles, the illumination stripe projected by each groove perfectly complement the stripe projected by the adjacent groove to give full illumination of the rectangular target area with uniform light intensity.

It is a common practice in non imaging Fresnel lens design to increase the density of the grooves as the distance from center is increased in attempt to keep groove depth under a certain limit. This limit enables low cost manufacturing of relatively large lenses by hot pressing on flat plastic sheets.

A similar approach can be taken with the Fresnel prism lens of the present invention as can be seen in FIG. 9, by increasing groove density in each rectangular Fresnel prism as prism distance from the center of the lens increase.

Groove density does not have to be constant in a given Fresnel prism and can vary to match with grooves in the adjacent prisms. However, for uniform illumination, grooves within the prism must be kept parallel, groove facet angle must be constant and groove depth kept under a limit determined by the manufacturing process.

Some pre determined margin can be designed into the lens, so that the illuminated target area is larger than the photovoltaic die, accounting for possible structural tolerances or sun tracking errors.

It is also common in solar energy concentrating Fresnel lenses to shape a grooved flat plastic lens to form a dome. Dome shaped Fresnel lens can optically be designed with grooves in the concave side of the lens, being smooth on the side facing the sun. This approach has the advantage that the lens can also be used as the protective cover of the power generating module without the risk of dust accumulating in the grooves.

Very similarly, the Fresnel prism array concentrating lens of the present invention can be shaped to form a multi facet dome, each facet being planar and grooved to form a single Fresnel prism that fully illuminates the target.

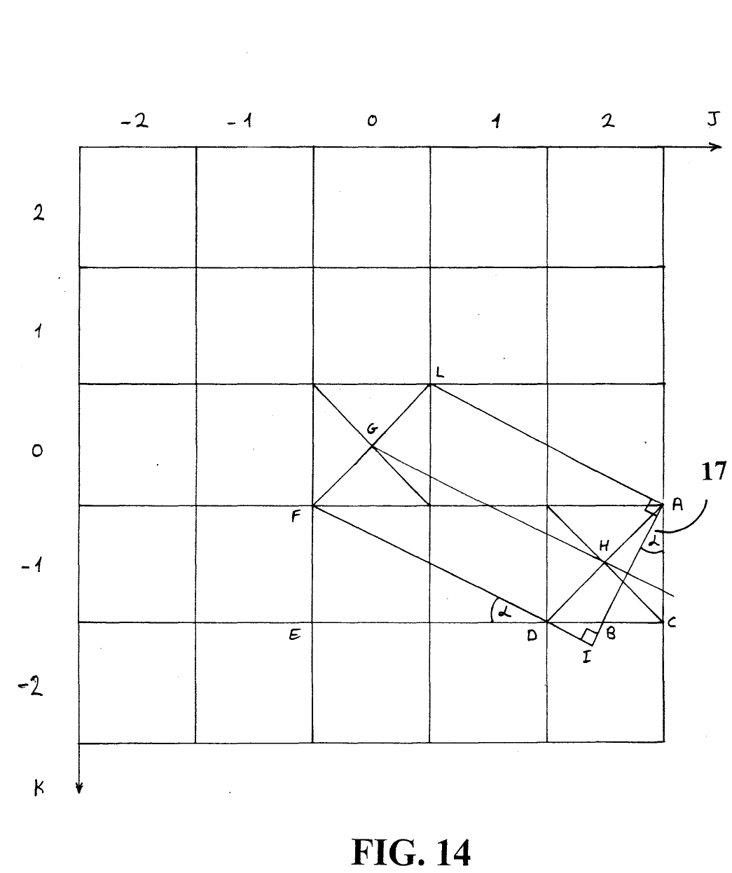

FIG. 14 is a geometric drawing for the lens of FIG. 9, showing only one arbitrary Fresnel groove orientation relative to the lens geometry for a specific square Fresnel prism.

Assuming that the illuminated target area conform with the Fresnel prism shape, a specific groove AB is required to project an illumination stripe with the same length and the same orientation as the groove. Therefore the groove has to be perpendicular to line HG connecting the centers of the said prism and the target area, hence the groove orientation angle 17 (Alpha) for each Fresnel prism can be calculated using common trigonometric theory.

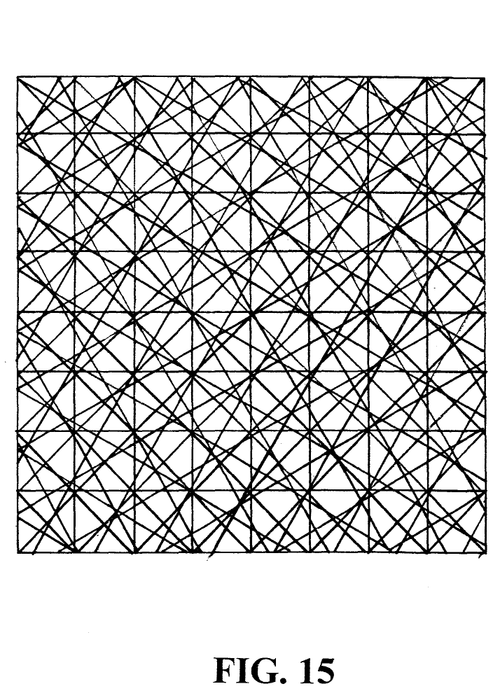

FIG. 15 shows and enlarged illustration of the illumination stripes projected on the square target by the parallel grooves of each Fresnel Prism in the lens in FIG. 9. It can be seen that the stripes complement each other and combine with illumination stripes projected by other prisms to uniformly illuminate a well defined square target area from several directions.

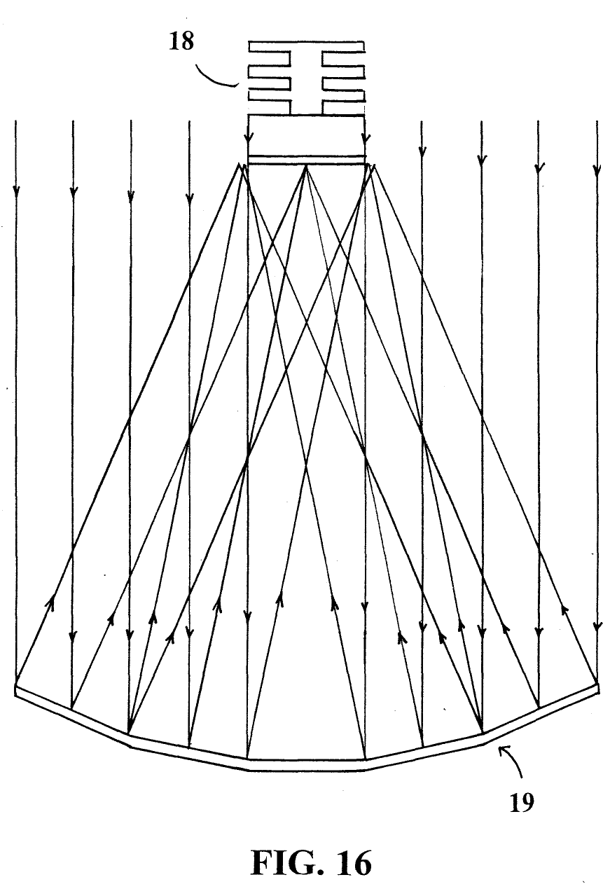

FIG. 16 shows a reflector design according to the present invention that can be implemented with a concentrating reflector 19 comprised of multiple planar mirrors, each mirror is reflecting incident solar rays to fully illuminate a common planar target area, the illumination from multiple planar reflecting mirrors combine together on the common target area, yielding concentrated light that fully and uniformly illuminates a photovoltaic cell that is located within the target area in front of the reflector, converting the concentrated solar radiation to electrical energy.

A heat sink 18 is thermally connected to the photovoltaic cell for dissipating the excessive heat that is generated by the cell.

When a solar concentrating reflector is compared to a lens, one of the advantages a reflector has is that it can better concentrate a wider spectrum of the solar illumination without the color dispersion that is inherent to any lens design.

Another advantage of a reflector is that it a can be made of durable opaque material coated with reflective metallic coating. Reflectors are very durable compared to transparent plastic lenses that are prone to performance degradation in long term ultraviolet exposure.

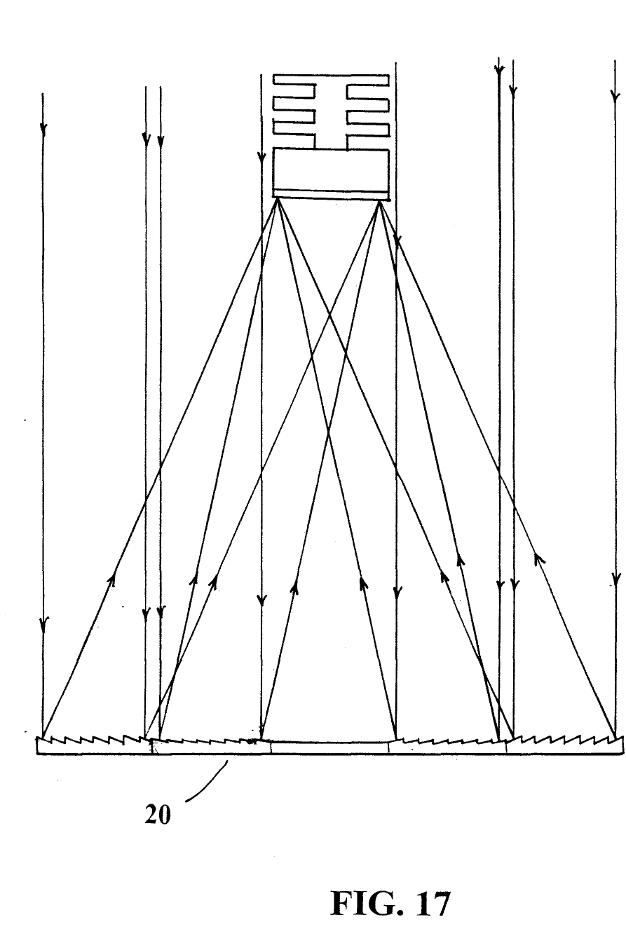

FIG. 17 shows a flat Fresnel mirror array Reflector 20 comprised of multiple planar Fresnel mirrors. This approach have the advantage of saving space and manufacturing cost while preserving other advantages of a reflector compared to a lens when used for solar energy concentration.

Each Fresnel mirror has multiple straight parallel grooves in the surface of a flat plastic material, all groove facet angles being constant in a specific Fresnel mirror and the surface of the grooves is coated with a highly reflective metallic layer.

A Fresnel mirror and a Fresnel prism are similar devices in terms that they both deflect parallel uniform incident light to a target area while preserving uniform intensity.

The combination of multiple Fresnel mirrors reflecting solar rays to a common target area enhance the light intensity without sacrificing the uniform nature of the sun illumination.

The level of concentration, depend on the number of Fresnel mirrors projecting light on the target area and generally, for a given photovoltaic cell, will be a function of the reflector area.

Fresnel prism arrays and Fresnel mirror arrays can be manufactured by pressing a metal die at an elevated temperature on a flat plastic material, thus creating a low cost relatively large lens or reflector.

The dies for circular Fresnel designs are usually made by cutting circular grooves into the metallic die on a special high precision rotary lath. This process is not suitable for Fresnel prism and mirror arrays since the grooves required for the Fresnel concentrators according to the present invention are non circular.

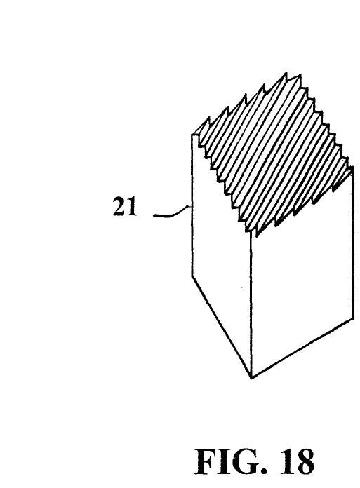

One preferred method for creating a die for the Fresnel prism and mirror arrays according to the present invention is showed in FIG. 18. Straight Fresnel grooves are being machined into a rectangular metal block designed to press a single specific Fresnel prism or mirror. Several such metal blocks are combined together to form a complete die for the whole Fresnel lens or reflector.

Another method for creating a Fresnel prism or mirror array die is by high precision numeric controlled machining or etching of the grooves into a single metallic block that is used to press the whole Fresnel concentrator.

Thus, a solar energy conversion module and a unique concentrator for use in such module have been provided that meets all the objects of the present invention. The design and the construction of the module are greatly simplified because no secondary optical concentrator or homogenizer is required due to the optical characteristics of the concentrator used.

This design approach yields three valuable results. First, the rectangular photovoltaic cell is fully illuminated with high intensity, uniform solar radiation by a specially designed concentrator made to fit the size, shape and concentration ratio required for a specific photovoltaic cell.

Second, a rectangular shape concentrator can be formed, allowing for a multi module panel design with good match between modules.

Third, a low cost, reduced weight, flat, Fresnel concentrator can be designed to meet the basic aspects of the present invention.

This is in contrary to conventional lenses which have been traditionally used for photovoltaic solar energy concentration.

While the invention has been described in terms of some preferred embodiments, there is no intent to limit the invention to the particular configurations illustrated in the drawings. For example, the concentrator shape can be square, rectangular, triangular or hexagonal and still fulfill the requirement of good match between modules.

Further, the cell shape can be rectangular, square, hexagonal, triangular, round or any other geometric shape, with the lens prisms being designed to illuminate a target area matching the cell's shape and size.

Further, the number of prisms and Fresnel grooves in each Fresnel prism is a matter of choice, and may vary from the number shown in the illustrations of the preferred embodiments.

Furthermore, a reflector as well as a Fresnel reflector can be designed to fulfill the basic aspects of the present invention.

What is claimed is:

1. A solar energy concentrating device, comprised of multiple optic elements, each optic element is directing incident solar rays to fully illuminate a common rectangular planar target area containing a rectangular photovoltaic cell thus illumination from a multitude of optical elements combine together on the common target area to yield high intensity uniform illumination of the photovoltaic cell;
a photovoltaic cell having positive and negative contacts, converting the concentrated solar energy to electrical energy,
a heat sink being thermally connected to the photovoltaic cell, dissipating excessive heat being generated by the cell,
a housing supporting at least one solar energy concentrating device, one photovoltaic cell and one heat sink, forming a solar energy generating module being mounted on a planar sun tracking structural grid being part of a multi module solar power generating panel.

2. A solar energy concentrating device of claim 1 wherein the optic elements are multiple prisms combined together to form a solid lens with the multi facet convex side of the lens facing the sun, each facet is a planar polygon in close match with adjacent facets of the lens, forming smooth geometric transitions between adjacent optic elements, each facet refracting the incident solar rays to fully illuminate a rectangular target area containing a rectangular photovoltaic cell.

3. A solar energy concentrating device of claim 2 wherein the lens side facing the target is staggered, forming a concave shape thus reducing lens weight.

4. A solar energy concentrating device of claim 2 wherein the lens side facing the target is concave with multi polygon planar facets, each facet being designed to fully illuminate the rectangular photovoltaic cell.

5. A solar energy concentrating device of claim 1 wherein the optical elements are planar polygon mirrors, each mirror reflecting incident solar rays to fully illuminate a common rectangular planar area containing a rectangular photovoltaic cell and a multitude of the polygon mirrors combine together to form a multi facet concave concentrating reflector.

6. A solar energy concentrating device of claims wherein the optic elements are Fresnel prisms arrayed to form a Fresnel prism concentrating lens, each Fresnel prism refracting incident solar rays to fully illuminate a photovoltaic cell and is comprised of multiple straight, parallel Fresnel grooves having planar facets.

7. A solar energy concentrating device of claims wherein the optic elements are Fresnel mirrors arrayed to form a Fresnel mirror concentrating reflector, each Fresnel mirror reflecting incident solar rays to fully illuminate a photovoltaic cell and is comprised of multiple straight, parallel Fresnel grooves having planar facets coated with reflective material.

8. The solar energy concentrating device of claim 6 wherein the distance between the straight parallel Fresnel grooves in each optic element is not constant.

9. The solar energy concentrating device of claim 6 wherein the parallel Fresnel grooves in an arbitrary optic element is perpendicular to the line connecting the center of that arbitrary Fresnel deflector with the center of the target area.

10. The solar energy concentrating devices of claim 6 wherein the optic elements have rectangular shape, matching the illumination requirements of a rectangular target area containing a photovoltaic cell.

11. The solar energy concentrating devices of claim 1 wherein a transparent cover protect the solar energy concentrating device and photovoltaic cell from the environment.

12. The solar energy concentrating device of claim 6 wherein grooves that are close to the Fresnel prism array lens center are facing the target area and Fresnel grooves out of the center area are facing the sun.

13. The solar energy concentrating device of claim 6 wherein the Fresnel prism array is made of plastic sheet shaped to form a multi facet dome, each facet being a planar polygon and grooved to form a single optic element.
